(19) United States
(12) Patent Application Publication
(10) Pub. No.: US 2016/0079068 A1
(43) Pub. Date: Mar. 17, 2016

(54) NONVOLATILE SEMICONDUCTOR STORAGE DEVICE AND METHOD OF MANUFACTURING THE SAME

(71) Applicant: KABUSHIKI KAISHA TOSHIBA, Minato-ku (JP)

(72) Inventors: Hirokazu ISHIGAKI, Yokkaichi (JP); Masaru Kito, Kuwana (JP)

(73) Assignee: KABUSHIKI KAISHA TOSHIBA, Minato-ku (JP)

(21) Appl. No.: 14/799,195

(22) Filed: Jul. 14, 2015

(30) Foreign Application Priority Data
Sep. 16, 2014 (JP) 2014-187675

(51) Int. Cl. H01L 21/28; H01L 29/423; H01L 29/792; H01L 27/115; H01L 29/66

(52) U.S. Cl. CPC H01L 21/28282; H01L 27/11568; H01L 29/66833; H01L 29/792; H01L 29/4234

(57) ABSTRACT

A nonvolatile semiconductor storage device includes a stack structure including first insulating films and first electrode films stacked alternately, the stack structure having a first through hole extending therethrough; a second electrode film provided above the stack structure, the second electrode film having a second through hole extending therethrough and communicating with the first through hole; a second insulating film provided above the second electrode film and having a third through hole extending therethrough and communicating with the second through hole; a semiconductor film provided along inner surfaces of the first and the second through holes; a memory film provided between the first electrode film and the semiconductor film; and a gate insulating film provided between the second electrode film and the semiconductor film; the third through hole becoming narrower toward an upper side of the stack direction and wider toward a lower side of a stack direction.

### CROSS-REFERENCE TO RELATED APPLICATION(S)

This application is based upon and claims the benefit of priority from Japanese Patent Application No. 2014-187675, filed on, Sep. 16, 2014 the entire contents of which are incorporated herein by reference.

### FIELD

Embodiments disclosed herein generally relate to a nonvolatile semiconductor storage device and a method of manufacturing the same.

### BACKGROUND

A stacked memory structure is being proposed as one solution for increasing the storage capacity while reducing the manufacturing cost in a nonvolatile semiconductor storage device. A stacked memory structure is typically manufactured by forming a stack structure by alternately stacking insulating films and electrode films above a semiconductor substrate, forming a through hole through the stack structure by lithography, and depositing a block layer, a charge storing layer, and a tunnel layer in the listed sequence into the through hole, followed by filling the through hole with a silicon pillar. This is further followed by formation of metal wirings serving as source lines and bit lines. In a stacked memory structure described above, memory cell transistors are formed at the intersections of the electrode films and the silicon pillars and the memory cell transistor serves as a memory cell.

When forming the through hole through the stack structure, a high-aspect-ratio through hole is formed through the stack structure by normally employing RIE (Reactive Ion Etching). Normally, holes formed by RIE are tapered, meaning that diameter in the upper portion of the hole is wider than the diameter in the lower portion of the hole. A tapered through hole causes the adjacent holes to be close to one another in the upper portion of the stack structure, possibly causing connection between the adjacent holes, and thereby causing a bit line leakage current.

### BRIEF DESCRIPTION OF THE DRAWINGS

FIG. 1 is one example of a perspective view of a nonvolatile semiconductor storage device of one embodiment.

FIG. 2 is an enlarged cross-sectional view schematically illustrating a portion of a select gate.

FIG. 3 is an enlarged cross-sectional view schematically illustrating a portion of a memory cell.

FIG. 4 is a circuit diagram of a memory string.

FIG. 5 is a cross-sectional view schematically illustrating one phase of a manufacturing process flow.

FIG. 6 is a cross-sectional view schematically illustrating one phase of a manufacturing process flow.

FIG. 7 is a cross-sectional view schematically illustrating one phase of a manufacturing process flow.

FIG. 8 is a cross-sectional view schematically illustrating one phase of a manufacturing process flow.

FIG. 9 is a cross-sectional view schematically illustrating one phase of a manufacturing process flow.

FIG. 10 is a cross-sectional view schematically illustrating one phase of a manufacturing process flow.

FIG. 11 is a cross-sectional view schematically illustrating one phase of a manufacturing process flow.

FIG. 12 is a cross-sectional view schematically illustrating one phase of a manufacturing process flow.

FIG. 13 is a cross-sectional view schematically illustrating one phase of a manufacturing process flow.

FIG. 14 is a cross-sectional view schematically illustrating one phase of a manufacturing process flow.

FIG. 15 is a cross-sectional view schematically illustrating one phase of a manufacturing process flow.

FIG. 16 is a cross-sectional view schematically illustrating one phase of a manufacturing process flow.

FIG. 17 is a cross-sectional view schematically illustrating one phase of a manufacturing process flow.

FIG. 18 is a cross-sectional view schematically illustrating one phase of a manufacturing process flow.

### DETAILED DESCRIPTION

An embodiment of a nonvolatile semiconductor storage device includes a stack structure including a plurality of first insulating films and a plurality of first electrode films stacked alternately one above another, the stack structure having a first through hole extending therethrough along a stack direction in which the first insulating films and the first electrode films are stacked; a second electrode film provided above the stack structure, the second electrode film having a second through hole extending therethrough in the stack direction and communicating with the first through hole; a second insulating film provided above the second electrode film, the second insulating film having a third through hole extending therethrough in the stack direction and communicating with the second through hole; a semiconductor film provided along an inner surface of the first through hole and the second through hole; a memory film provided between the first electrode film and the semiconductor film; and agate insulating film provided between the second electrode film and the semiconductor film; the third through hole becomes narrower toward an upper side of the stack direction and wider toward a lower side of the stack direction, and an electrically conductive material connected to the semiconductor film is provided in the third through hole.

### Embodiments

Embodiments are described hereinafter with reference to the drawings. In the drawings referred to in the following description, elements that are substantially identical are identified with identical reference symbols and are not be re-described. The drawings are schematic and thus, are not necessarily consistent with the actual correlation of thickness to planar dimensions and the actual thickness ratios between each of the layers.

### First Embodiment

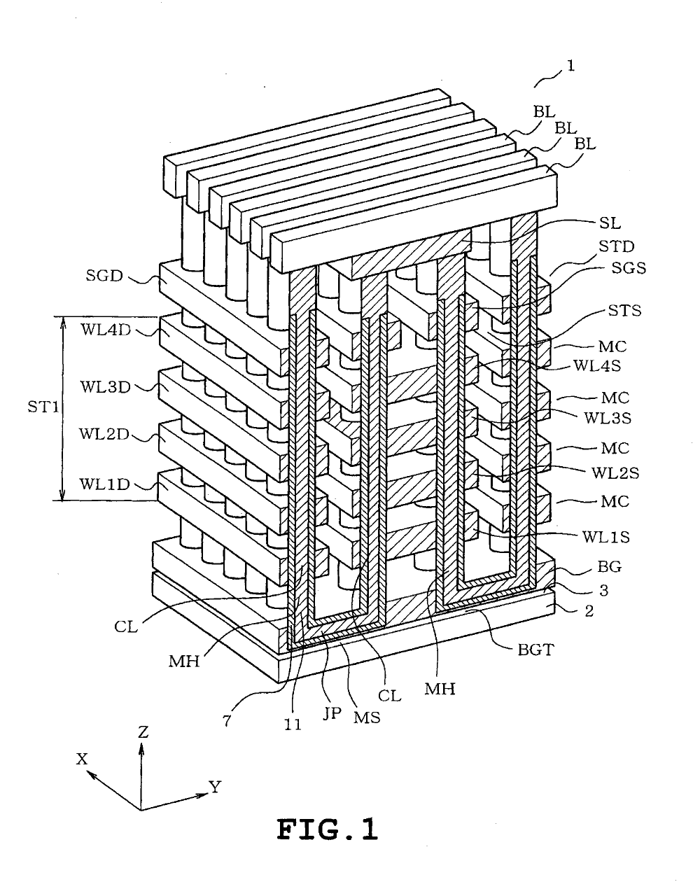

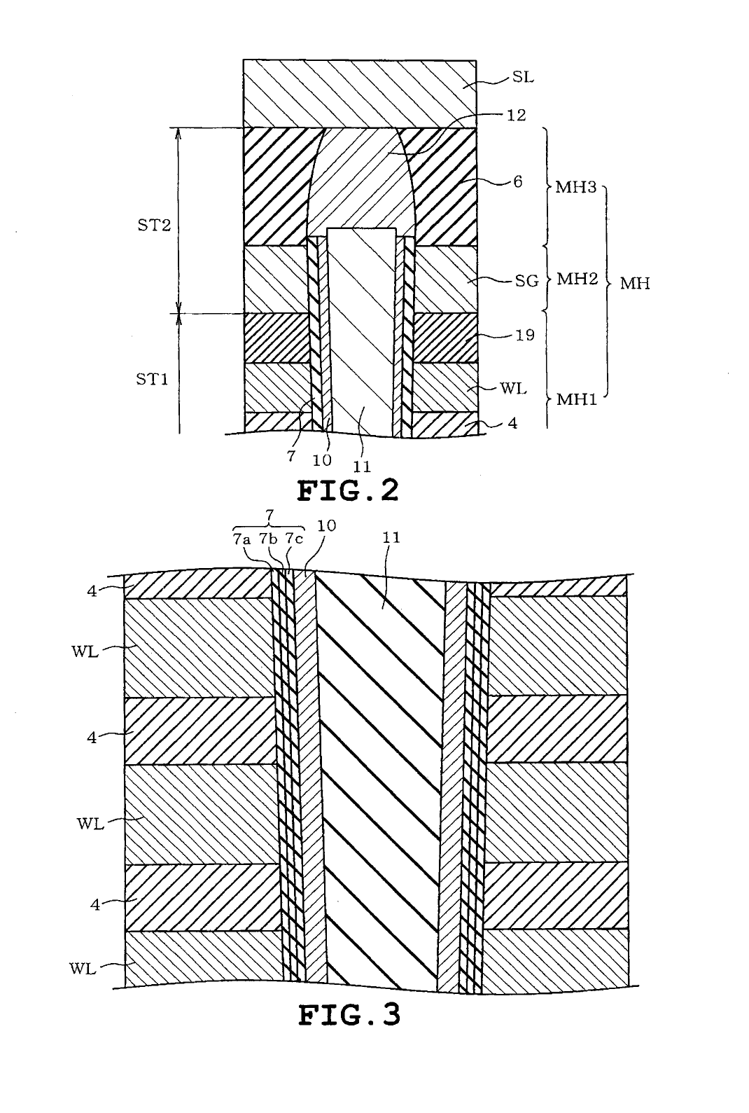

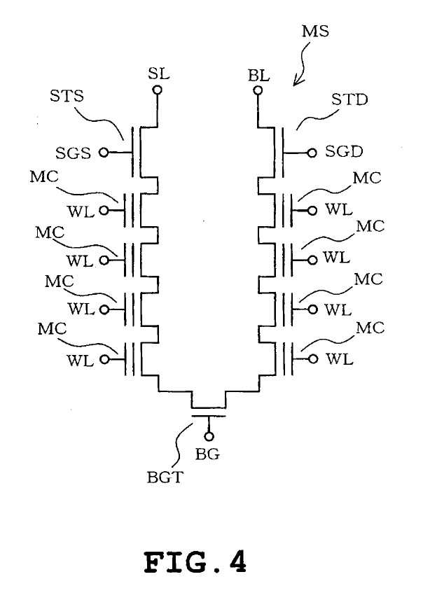

FIG. 1 pertains to a first embodiment and is one example of a perspective view schematically illustrating the structure of a nonvolatile semiconductor storage device. More specifically, FIG. 1 is a broken perspective view schematically illustrating a portion of the nonvolatile semiconductor storage device. In FIG. 1, some of the insulating structures are not illustrated to provide good visibility. FIG. 2 is one example of an enlarged cross-sectional view schematically illustrating a select gate portion. FIG. 3 is one example of an enlarged cross-sectional view schematically illustrating a memory cell portion. FIG. 4 is a circuit diagram of a memory string.

In the following description, XYZ orthogonal coordinate system is used for convenience of explanation. In the coordinate system, the X-axis direction and the Y-axis direction each indicates a direction along an axis parallel to main surface 3 of substrate 2 and crosses orthogonally with one another. The direction along an axis crossing orthogonally with both the X-axis and the Y-axis direction is referred to as the Z-axis direction. One of the two directions taken along the Z-axis direction and moving away from main surface 3 of substrate 2 is referred to as “up” or “upward direction” and the remaining other direction opposite of “up” or “upward direction” is referred to as “down” or “downward direction”. A portion of the broken surface illustrated in FIG. 1 represents the cross section taken along the Y-axis direction.

Next, a description will be given in detail on one example of a structure of nonvolatile semiconductor storage device 1 with reference to FIGS. 1, 2, and 3. As illustrated in FIG. 1, back gate BG is provided above substrate 2 via an insulating layer not shown. Back gate BG may be formed of for example an electrically conductive silicon layer containing impurities.

A stack including a plurality of insulating layers 4 (refer to FIG. 3) and a plurality of electrode layers WL1D, WL2D, WL3D, WL4D, WL1S, WL2S, WL3S, and WL4S disposed alternately above one another is provided above back gate BG.

Electrode layer WL1D and electrode layer WL1S are located in the same level, namely the first level counted from the bottom of the stack. Electrode layer WL2D and electrode layer WL2S are located in the same level, namely the second level counted from the bottom of the stack. Electrode layer WL3D and electrode layer WL3S are located in the same level, namely the third level counted from the bottom of the stack. Electrode layer WL4D and electrode layer WL4S are located in the same level, namely the fourth level counted from the bottom of the stack.

Electrode layer WL1D and electrode layer WL1S are divided in the Y-axis direction. Electrode layer WL2D and electrode layer WL2S are divided in the Y-axis direction. Electrode layer WL3D and electrode layer WL3S are divided in the Y-axis direction. Electrode layer WL4D and electrode layer WL4S are divided in the Y-axis direction.

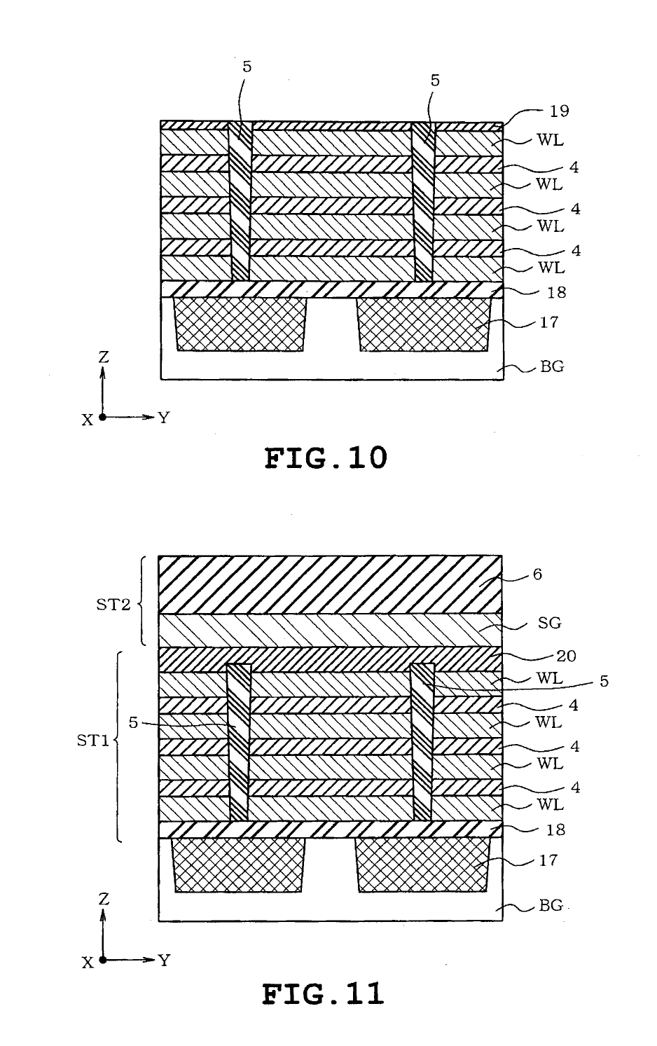

Insulating film 5 illustrated in FIGS. 10 and 11 are provided between electrode layer WL1D and electrode layer WL1S, between electrode layer WL2D and electrode layer WL2S, between electrode layer WL3D and electrode layer WL3S, and between electrode layer WL4D and electrode layer WL4S. Electrode layers WL1D to WL4D are provided between back gate BG and drain-side select gates SGD. Electrode layers WL1S to WL4S are provided between back gate BG and source-side select gates SGS.

FIG. 1 illustrates four layers of electrode layers for example. However, the electrode layers may come in any number of layers. In the following description, electrode layers WL1D to WL4D and electrode layers WL1S to WL4S may be generally referred to as electrode layer(s) WL for simplicity. Electrode layer WL may be formed of for example an electrically conductive silicon layer containing impurities. In this example, electrode layer WL is a polycrystalline silicon layer doped with impurities such as boron. Insulating layer 4 may be formed of a TEOS (tetraethoxysilane) layer containing a silicon oxide for example.

Drain-side select gate SGD is provided above electrode layer WL4D. Drain-side select gate SGD may be formed of for example an electrically conductive silicon layer containing impurities. In this example, drain-side select gate SGD is a polycrystalline silicon layer doped with impurities such as boron.

Source-side select gate SGS is provided above electrode layer WL4S. Source-side select gate SGS may be formed of for example an electrically conductive silicon layer containing impurities. In this example, source-side select gate SGS is a polycrystalline silicon layer doped with impurities such as boron.

Drain-side select gates SGD and source-side select gates SGS are divided in the Y-axis direction. In the following description, drain-side select gates SGD and source-side select gates SGS may not be distinguished and thus, generally referred to as select gate(s) SG for simplicity. Insulating film 6 is disposed above drain-side select gate SGD and source-side select gate SGS. Insulating film 6 may be formed for example of a TEOS film containing a silicon oxide.

Source line SL is provided above source-side select gate SGS. Source line SL comprises a metal layer for example. A plurality of bit lines BL are provided above drain-side select gate SGD and source line SL. Each bit line BL extends in the Y-axis direction.

In the above described structure, electrode layers WL1D to WL4D, electrode layers WL1S to WL4S, and insulating film 4 form first stack structure ST1 illustrated in FIG. 1. Drain-side select gates SGD, source-side select gates SGS, and insulating film 6 form second stack structure ST2 illustrated in FIG. 2.

A plurality of memory holes MH each shaped like a letter U are formed in back gate BG, first stack structure ST1 disposed above back gate BG, and second stack structure ST2 disposed above first stack structure ST1. As illustrated in FIG. 2 or 14, each memory hole MH is provided with first portion MH1, second portion MH2, and third portion MH3. First portion MH1 extends through first stack structure ST1. Second portion MH2 communicates with first portion MH1 and extends through select gate SG. Third portion MH3 communicates with second portion MH2 and extends through insulating film 6.

In this example, first portion MH1, second portion MH2, and third portion MH3 are round (circular) when viewed in the Z-axis direction, in other words, the direction in which the films are stacked. Stated differently, the cross-section of a plane orthogonal to the direction in which first portion MH1, second portion MH2, and third portion MH3 are stacked is round (circular). As illustrated in FIG. 2, third portion MH3 is formed so as to become narrower as the elevation becomes higher and thus, wider as the elevation becomes lower. First portion MH1 and second portion MH2 extend downward substantially in a straight vertical line, or so as to become slightly wider as the elevation becomes lower, or so as to become slightly narrower as the elevation becomes lower. The lower end portion of first portion MH1 reaches back gate BG. Connecting hole MHC illustrated in FIG. 14 is formed in the upper layer portion of back gate BG. Connecting hole MHC connects lower end of one first portion MH1 with the lower end of another first portion MH1 immediately adjacent in the Y-axis direction.

Memory film 7 is provided along the inner surfaces of first portion MH1, second portion MH2, and connecting hole MHC of memory hole MH. Memory film 7 includes an insulating block layer 7a, charge storing layer 7b, and an insulating tunnel layer 7c stacked in the listed sequence from the outer side (left side) as viewed in FIG. 3. Block layer 7a substantially allows no current flow even when a voltage falling within the range of drive voltage of nonvolatile semiconductor storage device 1 is applied. Block layer 7a is formed of for example a silicon oxide. Charge storing layer 7b is capable of trapping charge and is formed of for example a silicon nitride. Tunnel layer 7c is normally insulative; however, allows flow of tunnel current when a predetermined voltage falling within the range of drive voltage of nonvolatile semiconductor storage device 1 is applied. Tunnel layer 7c is formed of for example of a silicon oxide. To summarize, memory film 7 is configured for example as an ONO (Oxide Nitride Oxide) structure.

Channel film 10 comprising polysilicon for example is formed along the inner surface of memory film 7. Core material 11 is filled in the inner side of channel film 10. Core material 11 may be formed of for example a silicon oxide or a silicon nitride. Instead of completely filling the inner side of channel film 10, there may be unfilled portions where cavities exist in core material 11. Alternatively, channel film 10 may be configured to have cavities. Still alternatively, memory hole MH may be filled with channel film 10.

Third portion MH3 of memory hole MH extending through insulating film 6 is filled with conductive material 12 formed of silicon for example.

In the above described structure, one end of a pair of pillar portions of channel film 10 shaped like a letter U is connected to source line SL and the remaining other end is connected to bit line BL. As a result, channel film 10 is connected between bit line BL and source line SL. Channel film 10 shaped like a letter U and control gate electrode are disposed in the same periodicity in the Y-axis direction. However, because there is a half-period phase difference between channel film 10 and control gate electrode, the paired pillar portions associated with each channel film 10 shaped like a letter U extend through different electrode layers WL (control gate electrodes).

In nonvolatile semiconductor storage device 1 described above, pillar portions of channel film 10 serve as channels and electrode layers WL serve as gate electrodes. Thus, a vertical-type memory cell transistor MC is formed at the intersection of channel film 10 and electrode layer WL. Each memory cell transistor MC is configured to store charge in charge storing layer 7b of memory film 7 disposed between channel film 10 and electrode layer WL. In first stack structure ST1, a plurality of pillar portions are arranged in a matrix along the X-axis direction and the Y-axis direction. Thus, a plurality of memory cell transistors MC are laid out three-dimensionally along the X-axis direction, the Y-axis direction, and the Z-axis direction.

Further, drain-side select transistor STD is formed at the intersection of the pillar portions of channel film 10 and drain-side select gate electrode SGD. The pillar portions serve as a channel, whereas drain-side select gate electrode SGD serves as a gate electrode and memory film 7 serves as a gate insulating film. Source-side select transistor STS is formed at the intersection of the pillar portions of channel film 10 and source-side select gate electrode SGS. The pillar portions serve as a channel, whereas source-side select gate electrode SGS serves as a gate electrode and memory film 7 serves as a gate insulating film. These select transistors are vertical-type transistors like memory cell transistors described above.

Further, back gate transistor BGT is formed between back gate BG and connecting portion connecting the lower ends of a pair of pillar portions of channel film 10. The connecting portion serve as a channel, whereas back gate BG serves as a gate electrode and memory film 7 serves as a gate insulating film. Back gate BG serves as an electrode configured to control the conductive state of the connecting portion of channel film 10.

In the above described structure, a plurality of memory cell transistors MC are provided between drain-side select transistor STD and back gate transistor BGT. Electrode layers WL4D to WL1D serve as control gates of memory cell transistors MC. Similarly, a plurality of memory cell transistors MC are provided between source-side select transistor STS and back gate transistor BGT. Electrode layers WL1S to WL4S serve as control gates of memory cell transistors MC. Memory cell transistors MC, drain-side select transistor STD, back gate transistor BGT, and source-side select transistor STS are series connected through channel film 10 and form a single memory cell string MS shaped like a letter U.

As illustrated in FIG. 4, each memory string MS is provided with a circuit in which a plurality of memory cells MC are series connected between source line SL and bit line BL. Source-side select transistor STS is connected between source line SL and memory cell MC disposed in the source line side. Drain-side select transistor STD is connected between bit line BL and memory cell MC disposed in the drain side. Back gate transistor BGT is connected at a mid portion of memory string MS shaped like a letter U.

Each memory string MS is provided with a pair of pillar-shaped portions CL and connecting portion JP connecting the lower ends of the pair of pillar-shaped portions CL. Pillar-shaped portions CL extend in a direction in which a plurality of electrode layers WL of the stack structure are stacked. One example of such stack structure is first stack structure ST1 described earlier. Connecting portion JP is embedded in back gate BG. Memory cells MC are disposed three-dimensionally in the X-axis direction, Y-axis direction, and the Z-axis direction since multiple memory cell strings MS are disposed in the X-axis direction and the Y-axis direction.

Memory strings MS are provided in memory cell array region of substrate 2. A peripheral circuit for controlling the memory cell array is provided for example in the periphery of the memory cell array region of substrate 2.

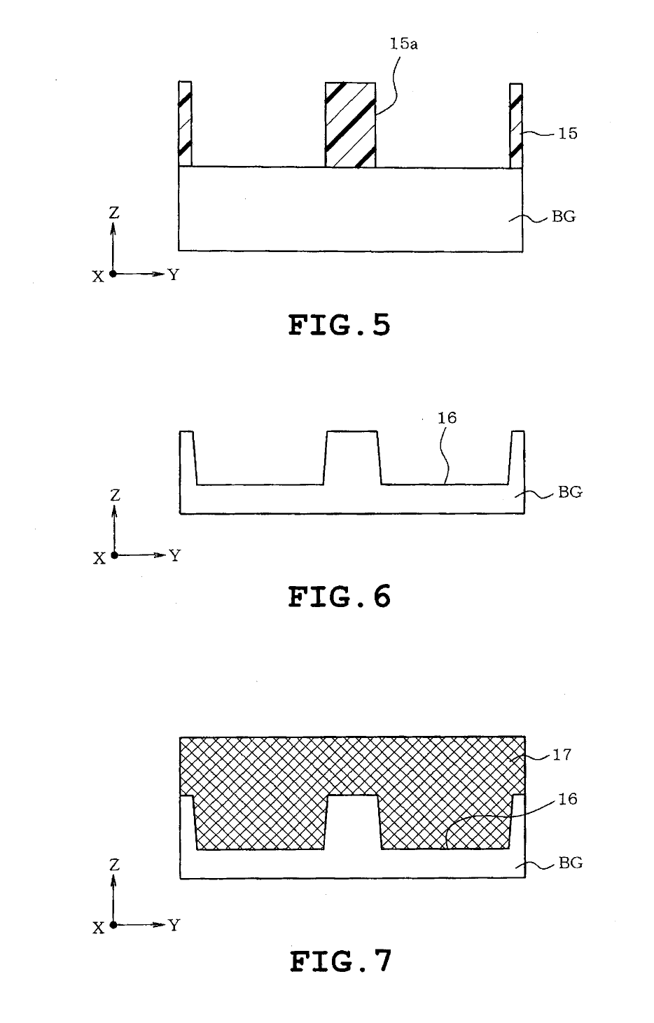

Next, a description will be given on a method of manufacturing nonvolatile semiconductor storage device 1 of the present embodiment with reference to FIGS. 5 to 18. FIGS. 5 to 18 are schematic cross-sectional views illustrating one example of a manufacturing process flow of nonvolatile semiconductor storage device 1. Back gate BG is provided above substrate 2 via an insulating layer not shown. Back gate BG comprises for example a polycrystalline silicon layer doped with impurities such as boron. Resist 15 is formed above back gate BG as illustrated in FIG. 5. Resist 15 is patterned to possess selectively formed openings 15a.

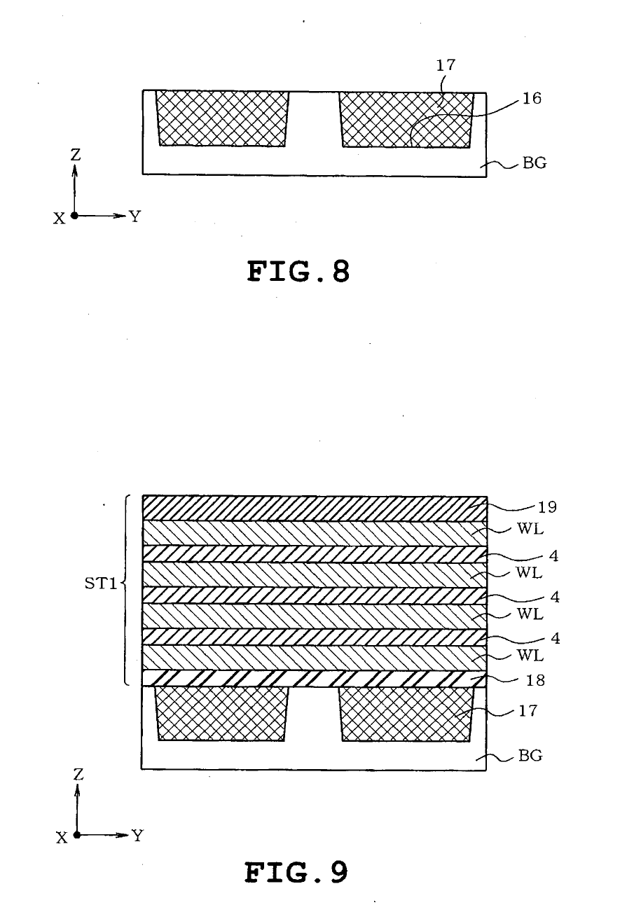

Next, as illustrated in FIG. 6, back gate BG is selectively dry etched using resist 15 as a mask. Recess 16 is formed into back gate BG in the above described manner. Then, as illustrated in FIG. 7, recess 16 is filled with sacrificial film 17. Sacrificial film 17 comprises a silicon nitride film or a non-doped silicon film. Then, as illustrated in FIG. 8, etching is performed across the entire surface of sacrificial film 17 to expose the surfaces of back gate BG located between recesses 16.

Next, as illustrated in FIG. 9, insulating film 18 is formed above back gate BG. Then, first stack structure ST1 is formed above insulating film 18. First stack structure ST1 includes a plurality of electrode layers WL and a plurality of insulating layers 4. Electrode layers WL and insulating layers 4 are stacked alternately one above the other so that insulating layer 4 is disposed between electrode layers WL. Insulating film 19 is formed above the uppermost electrode layer WL. First stack structure ST1 may be configured to include insulating film 18 and insulating film 19. Insulating layer 4 and insulating films 8 and 9 comprise for example a TEOS layer containing a silicon oxide.

Then, first stack structure ST1 is divided and trenches reaching insulating film 18 are formed by photolithography and etching. The trenches are thereafter filled with insulating film 5 as illustrated in FIG. 10. After filling the trenches with insulating film 5, insulating film 19 is exposed by etching the entire surface.

Referring next to FIG. 11, insulating film 20 is formed above insulating film 19. Further, second stack structure ST2 including select gate SG and insulating layer 6 is formed above insulating film 20. In this example, select gate SG is formed above insulating film 20 and insulating layer 6 is formed above select gate SG. Second stack structure ST2 may be configured to include insulating layer 6. Select gate SG may be configured by stacking a plurality of conductive films with one or more insulating films disposed therebetween.

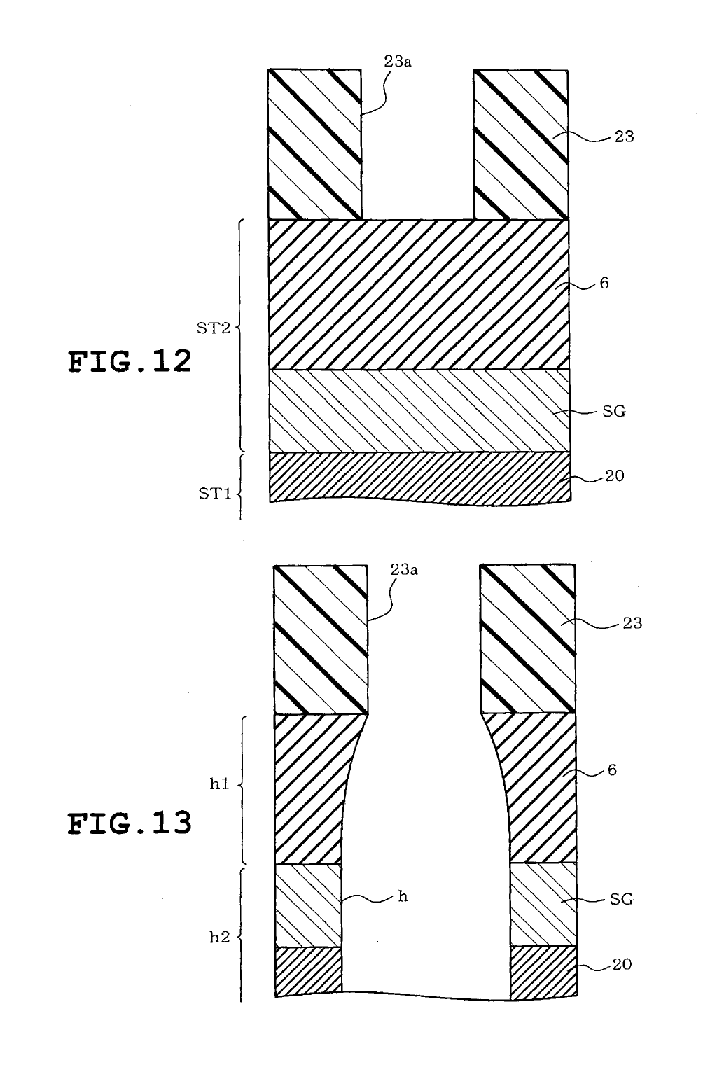

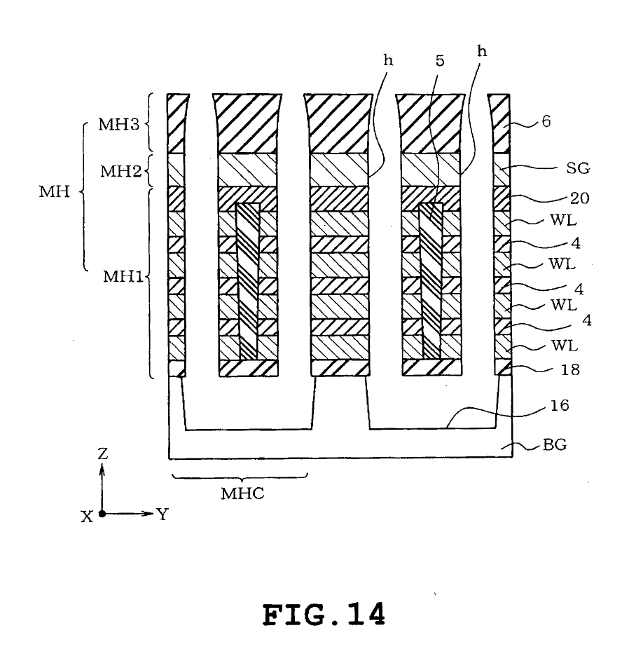

Referring next to FIG. 12, resist 23 is formed above insulating layer 6. Resist 23 is patterned to possess selectively formed opening 23a. Referring next to FIG. 13, hole h is formed by etching first stack structure ST1 and second stack structure ST2 disposed above back gate BG by RIE (Reactive Ion Etching) using resist 23 as a mask.

In this example, hole h includes portion h1 and portion h2 which are shaped differently. When viewed from the Z-axis direction, portion h1 located in insulating layer 6 is for example round (circular). Portion h1 is formed so as to become narrower as the elevation becomes higher and thus, wider as the elevation becomes lower. In other words, the upper portion of portion h1 is narrower than lower portion of portion h1. Portion h2, in other words, the remaining portion of hole h extend downward substantially in a straight vertical line, or so as to become slightly wider as the elevation becomes lower, or so as to become slightly narrower as the elevation becomes lower. The above described shapes of portion h1 and portion h2 of hole h are achieved by controlling the etching conditions of RIE.

The above described etching causes the lower portion of hole h to reach sacrificial film 17 and thereby exposing sacrificial film 17 at the bottom portion of hole h. A pair of holes h is disposed above sacrificial film 17 so that insulating film 18 located substantially in the center of sacrificial film 17 is disposed between the pair of holes h.

Referring next to FIG. 14, sacrificial film 17 is removed via holes h by wet etching. Examples of an etching liquid used in the wet etching includes, an alkaline chemical liquid such as KOH (potassium hydroxide) solution or a phosphoric acid solution (H₃PO₄) which exhibits controlled etch rates at different temperatures.

Recess 16 is formed in back gate BG by removing sacrificial film 17. A pair of holes h is connected by a single recess 16. In other words, the lower ends of a pair of holes h are connected to a common recess 16 to forma single memory hole MH shaped like a letter U.

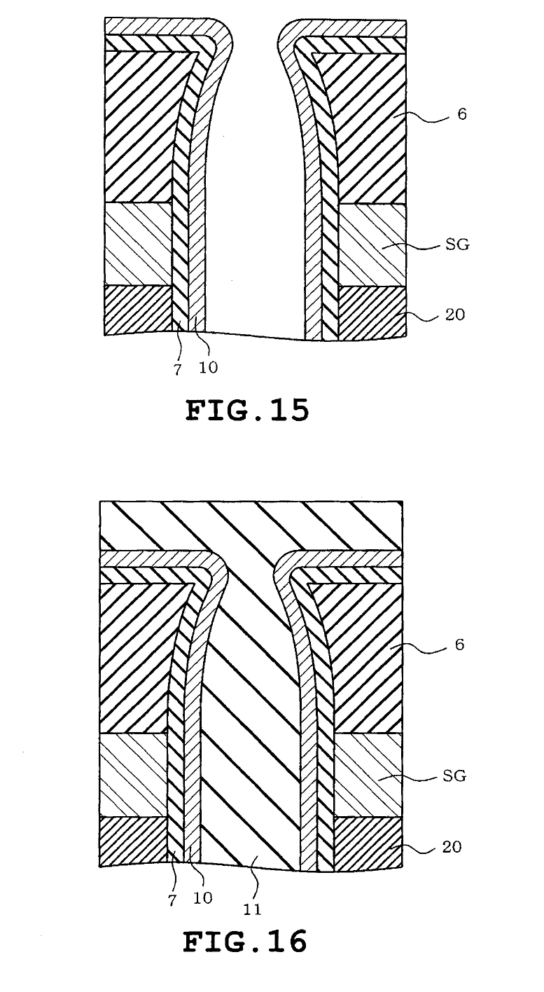

Next, as illustrated in FIG. 15, memory film 7 is formed along the inner surface of memory hole MH and along the upper surface of insulating layer 6. Memory film 7 includes an block layer 7a, charge storing layer 7b, and tunnel layer 7c stacked in the listed sequence from the outer side (left side) as viewed in FIG. 3 which are formed for example by CVD. Block layer 7a comprises a silicon oxide for example. Charge storing layer 7b comprises a silicon nitride for example. Tunnel layer 7c comprises a silicon oxide for example. Channel film 10 comprising polysilicon for example is formed along memory film 7. Channel film 10 comprises a polycrystalline silicon film for example formed by CVD. Referring next to FIG. 16, core material 11 is filled in the inner side of channel film 10 by CVD for example. Core material 11 may be formed of for example a silicon oxide or a silicon nitride.

Then, core material 11 is etched back so that the upper surface thereof is located at position P1 illustrated in FIG. 17. Further, channel film 10 and memory film 7 are etched back so that the upper surfaces of channel film 10 and memory film 7 are located at position P2 illustrated in FIG. 17. Recess 24 is formed in the upper portion of insulating layer 6 in the above described manner.

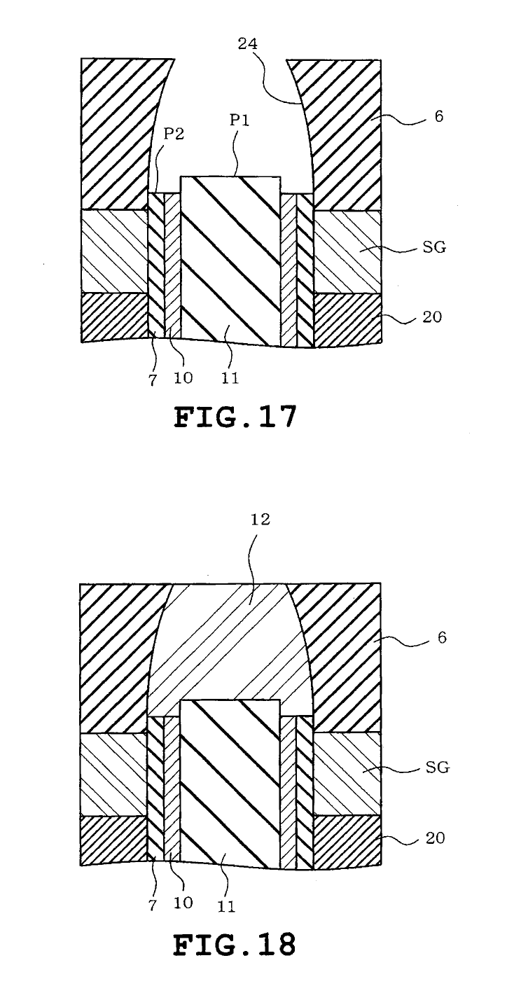

Referring next to FIG. 18, recess 24 is filled with conductive material 12. Conductive material 12 comprises a semiconductor material doped with impurities. One example of conductive material 12 may be a polycrystalline silicon film formed for example by CVD. Conductive material 12 is further etched back to expose the surface of insulating layer 6. The structure illustrated in FIG. 18 is obtained by the above described process flow. The structure is thermally treated so that the impurities contained in the conductive material 12 are diffused into channel film 10. As a result, a reliable contact is established between conductive material 12 and channel film 10.

Referring next to FIG. 2, metal wires such as source lines SL or bit lines BL are formed above conductive material 12.

In the above described embodiment, third portion MH3 of memory hole MH is formed so as to become narrower as the elevation becomes higher and wider as the elevation becomes lower as illustrated in FIG. 2. In other words, the upper portion of third portion MH3 is narrower than lower portion of third portion MH3. As a result, it is possible to prevent the adjacent memory holes MH from being connected at the upper portion of insulating film 6 when memory holes MH are formed through insulating film 6 (second stack structure ST2). It is thus, possible to prevent bit line leakage current.

Further in the present embodiment, impurities contained in conductive material 12 are arranged to diffuse into channel film 10 by thermal treatment after filling the inner portion of third portion MH3 of memory hole MH with conductive material 12 comprising silicon for example. As a result, it is possible to establish reliable contact between conductive material 12 and channel film 10.

### Other Embodiments

The following structure may be employed in addition to the structure discussed in the above described embodiment.

Memory string MS shaped like a letter U in the above described embodiment may be configured to be shaped like a letter I.

The nonvolatile semiconductor storage device of the present embodiment is capable of preventing the through holes located adjacent to one another at the upper portion of the stack structure from being connected when forming the through holes.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor storage device comprising:
a stack structure including a plurality of first insulating films and a plurality of first electrode films stacked alternately one above another, the stack structure having a first through hole extending therethrough along a stack direction in which the first insulating films and the first electrode films are stacked;
a second electrode film provided above the stack structure, the second electrode film having a second through hole extending therethrough in the stack direction and communicating with the first through hole;
a second insulating film provided above the second electrode film, the second insulating film having a third through hole extending therethrough in the stack direction and communicating with the second through hole;
a semiconductor film provided along an inner surface of the first through hole and the second through hole;
a memory film provided between the first electrode film and the semiconductor film; and
a gate insulating film provided between the second electrode film and the semiconductor film;
the third through hole becoming narrower toward an upper side of the stack direction and wider toward a lower side of the stack direction, and an electrically conductive material connected to the semiconductor film is provided in the third through hole.

2. The device according to claim 1, wherein the semiconductor film includes a hollow portion, the hollow portion being filled with an insulating material.

3. The device according to claim 2, wherein a position of an upper portion of the semiconductor film and a position of an upper portion of the gate insulating film in the stack direction are higher than a position of an undersurface of the second insulating film in the stack direction.

4. The device according to claim 1, wherein the second through hole and the first through hole are shaped so as to become narrower toward a lower side of the stack direction.

5. The device according to claim 1, wherein a first cross section of the first through hole, a second cross section of the second through hole, and a third cross section of the third through hole taken along planes orthogonal to the stack direction are circular.

6. The device according to claim 2, wherein a position of an upper portion of the insulating material in the stack direction is higher than a position of an upper portion of the semiconductor film in the stack direction and a position of an upper portion of the gate insulating film in the stack direction.

7. The device according to claim 6, wherein the first electrode film and the second electrode film each comprises an electrically conductive silicon layer, and the first insulating film and the second insulating film each comprises a tetraethoxysilane layer containing a silicon oxide.

8. The device according to claim 7, wherein the semiconductor film serves as a channel film comprising polysilicon.

9. The device according to claim 8, wherein the memory film and the gate insulating film each include a stack of an insulative block layer, a charge storing layer, and an insulative tunnel layer.

10. The device according to claim 9, wherein the block layer comprises a silicon oxide film, the charge storing layer comprises a silicon nitride film, and the tunnel layer comprises a silicon oxide film.

11. The device according to claim 10, wherein the insulating material comprises a silicon oxide film or a silicon nitride film.

12. The device according to claim 2, wherein the insulating material is provided with a hollow portion.

13. A method of manufacturing a nonvolatile semiconductor storage device comprising:
forming a stack structure by alternately stacking a plurality of first insulating films and a plurality of first electrode films one above another,
forming a second electrode film above the stack structure;
forming a second insulating film above the second electrode film;
forming a through hole extending through the second insulating film, the second electrode film, and the stack structure in a stack direction in which the first insulating film and the first electrode film are stacked;
forming a memory film along an inner surface of the through hole; and
forming a semiconductor film along the memory film, the through hole being formed through the second insulating film so that an upper portion thereof becomes narrower toward an upper side of the stack direction and wider toward a lower side of the stack direction.

14. The method according to claim 13, further comprising filling the through hole with an electrically conductive material, the electrically conductive material being connected to the semiconductor film.

15. The method according to claim 14, wherein a hollow portion is formed in the semiconductor film and the hollow portion is filled with an insulating material.

16. The method according to claim 15, wherein forming the through hole through the second insulating film is performed by reactive ion etching.

17. The method according to claim 16, wherein forming the memory film along the inner surface of the through hole includes forming a stack of an insulative block layer, a charge storing layer, and a insulative tunnel layer by a chemical vapor deposition.

18. The method according to claim 17, wherein forming the semiconductor film along the memory film includes forming polysilicon serving as a channel film by a chemical vapor deposition.

19. The method according to claim 18, wherein filling the hollow portion of the semiconductor film with the insulating material includes filling a silicon oxide film or a silicon nitride film by chemical vapor deposition.

20. The method according to claim 19, wherein filling the through hole with the electrically conductive material connected to the semiconductor material includes filling a polysilicon film doped with impurities by chemical vapor deposition.
